(19) United States
(12) Patent Application Publication
(10) Pub. No.: US 2022/0306899 A1
(43) Pub. Date: Sep. 29, 2022

(54) POLISHING COMPOSITIONS AND METHODS OF USING THE SAME

(71) Applicant: Fujifilm Electronic Materials U.S.A., Inc., N. Kingstown, RI (US)

(72) Inventors: Qingmin Cheng, Mesa, AZ (US); Bin Hu, Chandler, AZ (US); Kristopher D. Kelly, Gilbert, AZ (US); Yannan Liang, Gilbert, AZ (US); Hyosang Lee, Chandler, AZ (US); Eric Turner, Phoenix, AZ (US); Abhudaya Mishra, Gilbert, AZ (US)

(21) Appl. No.: 17/699,655

(22) Filed: Mar. 21, 2022

Related U.S. Application Data
(60) Provisional application No. 63/166,340, filed on Mar. 26, 2021.

(51) Int. Cl. C09G 1/02; H01L 21/321

(52) U.S. Cl. CPC C09G 1/02; H01L 21/3212

(57) ABSTRACT

This disclosure relates to polishing compositions that include (1) at least one abrasive; (2) at least one organic acid or a salt thereof; (3) at least one amine compound; (4) at least one nitride removal rate reducing agent; and (5) an aqueous solvent.

### CROSS-REFERENCE TO RELATED APPLICATION

The present application claims priority to U.S. Provisional Application Ser. No. 63/166,340, filed on Mar. 26, 2021, the contents of which are hereby incorporated by reference in their entirety.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing materials using abrasion-based physical processes concurrently with surface-based chemical reactions. In general, a CMP process involves applying a CMP slurry (e.g., an aqueous chemical formulation) to a wafer surface while contacting the wafer surface with a polishing pad and moving the polishing pad in relation to the wafer. Slurries typically include an abrasive component and dissolved chemical components, which can vary significantly depending upon the materials (e.g., metals, metal oxides, metal nitrides, dielectric materials such as silicon oxide and silicon nitride, etc.) present on the wafer that will be interacting with the slurry and the polishing pad during the CMP process.

Molybdenum is a transition metal with very low chemical reactivity, high hardness, great conductivity, strong wear resistance, and high corrosion-resistance. Molybdenum can also form heteropoly and alloy compounds with other elements. With respect to its use in the microelectronic industry, molybdenum and alloys thereof may find use as interconnects, diffusion barriers, photo masks, and plug filling materials. However, because of its hardness and chemical resistance, molybdenum is difficult to be polished with high removal rate and low defectivity, which presents a challenge for CMP of molybdenum containing substrates.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

This disclosure is based on the unexpected discovery that certain polishing compositions can selectively remove molybdenum (Mo) and/or its alloys relative to other materials (e.g., silicon nitride) in a semiconductor substrate during a CMP process in a controlled manner with an excellent corrosion resistance and a low static etch rate for Mo.

In one aspect, this disclosure features polishing compositions that include at least one abrasive; at least one organic acid or a salt thereof; at least one amine compound, the at least one amine compound including an amino acid, an alkylamine having a 6-24 carbon alkyl chain, or a mixture thereof; at least one nitride removal rate reducing agent; and an aqueous solvent; in which the polishing composition has a pH of about 2 to about 9.

In yet another aspect, this disclosure features methods that includes (a) applying a polishing composition described herein to a substrate containing molybdenum or an alloy thereof on a surface of the substrate; and (b) bringing a pad into contact with the surface of the substrate and moving the pad in relation to the substrate.

### DETAILED DESCRIPTION OF THE DISCLOSURE

The present disclosure relates to polishing compositions and methods for polishing semiconductor substrates using the same. In some embodiments, this disclosure relates to polishing compositions used for polishing substrates that include at least one portion containing molybdenum (Mo) metal and its alloys. In one or more embodiments, this disclosure relates to a polishing composition used for polishing substrates that include at least one portion containing molybdenum (Mo) metal and its alloys and has the ability to stop on (i.e., does not substantially remove) a dielectric material (e.g., a nitride such as silicon nitride).

In one or more embodiments, a polishing composition described herein can include at least one abrasive, at least one organic acid or a salt thereof, at least one amine compound, at least one nitride removal rate reducing agent, and an aqueous solvent. In one or more embodiments, a polishing composition according to the present disclosure can include from about 0.01% to about 50% by weight of at least one abrasive, from about 0.001% to about 10% by weight of at least one organic acid, from about 0.001% to about 5% by weight of at least one amine compound, from about 0.001% to about 10% at least one nitride removal rate reducing agent, and the remaining percent by weight (e.g., from about 30% to about 99.99% by weight) of an aqueous solvent (e.g., deionized water).

In one or more embodiments, the present disclosure provides a concentrated polishing composition that can be diluted with water prior to use by up to a factor of two, or up to a factor of four, or up to a factor of six, or up to a factor of eight, or up to a factor of ten, or up to a factor of 15, or up to a factor of 20. In other embodiments, the present disclosure provides a point-of-use (POU) polishing composition, comprising the above-described polishing composition, water, and optionally an oxidizer.

In one or more embodiments, a POU polishing composition can include from about 0.01% to about 25% by weight of at least one abrasive, from about 0.001% to about 1% by weight of at least one organic acid, from about 0.001% to about 0.5% by weight of at least one amine compound, from about 0.001% to about 1% by weight of at least one nitride removal rate reducing agent, and the remaining percent by weight (e.g., from about 65% to about 99.99% by weight) of an aqueous solvent (e.g., deionized water).

In one or more embodiments, a concentrated polishing composition can include from 0.02% to about 50% by weight of at least one abrasive, from about 0.01% to about 10% by weight of at least one organic acid, from about 0.01% to about 5% by weight of at least one amine compound, from about 0.01% to about 10% by weight of at least one nitride removal rate reducing agent, and the remaining percent by weight (e.g., from about 35% to about 99.98% by weight) of an aqueous solvent (e.g., deionized water).

In one or more embodiments, the polishing compositions described herein can include at least one (e.g., two or three) abrasive. In one or more embodiments, the at least one abrasive is selected from the group consisting of cationic abrasives, substantially neutral abrasives, and anionic abrasives. In one or more embodiments, the at least one abrasive is selected from the group consisting of alumina, silica, titania, ceria, zirconia, co-formed products thereof (i.e., co-formed products of alumina, silica, titania, ceria, or zirconia), coated abrasives, surface modified abrasives, and mixtures thereof. In some embodiments, the at least one abrasive does not include ceria. In some embodiments, the at least one abrasive has a high purity, and can have less than about 100 ppm of alcohol, less than about 100 ppm of ammonia, and less than about 100 ppb of an alkali cation such as sodium cation. The abrasive can be present in an amount of from about 0.01% to about 12% (e.g., from about 0.5% to about 10%) based on the total weight of a POU polishing composition, or any subranges thereof.

In one or more embodiments, the abrasive is a silica-based abrasive, such as one selected from the group consisting of colloidal silica, fumed silica, and mixtures thereof. In one or more embodiments, the abrasive can be surface modified with organic groups and/or non-siliceous inorganic groups. For example, the cationic abrasive can include terminal groups of formula (I):

—Oₘ—X—(CH₂)ₙ—Y (I),

in which m is an integer from 1 to 3; n is an integer from 1 to 10; X is Al, Si, Ti, Ce, or Zr; and Y is a cationic amino or thiol group. As another example, the anionic abrasive can include terminal groups of formula (I):

—Oₘ—X—(CH₂)ₙ—Y (I),

in which m is an integer from 1 to 3; n is an integer from 1 to 10; X is Al, Si, Ti, Ce, or Zr; and Y is an acid group.

In one or more embodiments, the abrasive described herein can have a mean particle size of from at least about 1 nm (e.g., at least about 5 nm, at least about 10 nm, at least about 20 nm, at least about 40 nm, at least about 50 nm, at least about 60 nm, at least about 80 nm, or at least about 100 nm) to at most about 1000 nm (e.g., at most about 800 nm, at most about 600 nm, at most about 500 nm, at most about 400 nm, or at most about 200 nm). As used herein, the mean particle size (MPS) is determined by dynamic light scattering techniques.

In one or more embodiments, the at least one abrasive is in an amount of from at least about 0.01% (e.g., at least about 0.05%, at least about 0.1%, at least about 0.2%, at least about 0.4%, at least about 0.5%, at least about 0.6%, at least about 0.8%, at least about 1%, at least about 1.2%, at least about 1.5%, at least about 1.8%, or at least about 2%) by weight to at most about 50% (e.g., at most about 45%, at most about 40%, at most about 35%, at most about 30%, at most about 25%, at most about 20%, at most about 15%, at most about 12%, at most about 10%, at most about 5%, at most about 4%, at most about 3%, at most about 2%, at most about 1%) by weight of the polishing compositions described herein.

In one or more embodiments, the polishing compositions described herein include at least one (e.g., two or three) organic acid or a salt of the organic acid. In some embodiments, the organic acid can be a carboxylic acid that includes one or more (e.g., two, three, or four) carboxylic acid groups, such as a dicarboxylic acid or a tricarboxylic acid. In one or more embodiments, the organic acid is selected from the group consisting of gluconic acid, lactic acid, citric acid, tartaric acid, malic acid, glycolic acid, malonic acid, formic acid, oxalic acid, acetic acid, propionic acid, peracetic acid, succinic acid, lactic acid, amino acetic acid, phenoxyacetic acid, bicine, diglycolic acid, glyceric acid, and mixtures thereof. Without wishing to be bound by theory, it is believed that the organic acid (such as those described above) can be used as an effective metal removal rate enhancer in the polishing compositions described herein to improve the removal rate of molybdenum and/or its alloys in a semiconductor substrate.

In one or more embodiments, the at least one organic acid or a salt thereof is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%, at least about 1%, at least about 1.3%, or at least about 1.5%) by weight to at most about 10% (e.g., at least about 9%, at least about 8%, at least about 7%, at least about 6%, at least about 5%, at least about 4%, at least about 3%, at least about 2.5%, at most about 2.2%, at most about 2%, at most about 1.7%, at most about 1.5%, at most about 1.2%, at most about 1%, at most about 0.7%, at most about 0.5%, at most about 0.2%, at most about 0.15%, at most about 0.1%, at most about 0.07%, or at most about 0.05%) by weight of the polishing compositions described herein. In embodiments where more than one organic acid is included in the polishing composition, the above ranges may apply to each organic acid independently, or to the combined amount of organic acids within the composition.

In one or more embodiments, the polishing compositions described herein include at least one (e.g., two or three) amine compound. In one or more embodiments, the amine compound can be an amino acid. In one or more embodiments, the amine compound can be an amino acid selected from the group consisting of tricine, alanine, histidine, valine, phenylalanine, proline, glutamine, aspartic acid, glutamic acid, arginine, lysine, tyrosine, serine, leucine, isoleucine, glycine, tryptophan, asparagine, cysteine, methionine, aspartate, glutamate, threonine, taurine and mixtures thereof. In one or more embodiments, the amine compound can be an amino acid that includes at least two amino groups (e.g., histidine, lysine, arginine, etc.). In one or more embodiments, the amine compound can be an alkylamine compound that has at least one (e.g., two or three) alkyl chain that includes between 6 and 24 (i.e., 6, 7, 8, 9, 10, 11, 12, 13, 14, 15, 16, 17, 18, 19, 20, 21, 22, 23, or 24) carbons. In one or more embodiments, the alkyl chain can be a linear, branched, or cyclic alkyl group. In one or more embodiments, the alkylamine compound can be a primary, secondary, tertiary, or cyclic amine compound. In one or more embodiments, the alkylamine compound can be an alkoxylated amine (e.g., including ethoxylate and/or propoxylate groups). In one or more embodiments, the alkoxylated amine can include from 2 to 100 ethoxylate and/or propoxylate groups. In some embodiments, the at least one alkylamine compound has an alkyl chain that includes between 6 and 18 carbons. In some embodiments, the alkylamine is selected from the group consisting of hexylamine, octylamine, decylamine, dodecylamine, tetradecylamine, pentadecylamine, hexadecylamine, octadecylamine, cyclohexylamine, dicyclohexylamine, and mixtures thereof. In some embodiments, the polishing compositions described herein can include both at least one amino acid and at least one alkylamine compound. Without wishing to be bound by theory, it is surprising that the amine compounds described above can significantly reduce or minimize the corrosion or etching of molybdenum and/or its alloys in a semiconductor substrate, thereby controlling the removal rate of molybdenum and/or its alloys.

In one or more embodiments, the at least one amine compound is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%) by weight to at most about 5% (e.g., at most about 4.5%, at most about 4%, at most about 3.5%, at most about 3%, at most about 2.5%, at most about 2%, at most about 1.5%, at most about 1%, at most about 0.8%, at most about 0.6%, at most about 0.5%, at most about 0.4%, at most about 0.2%, at most about 0.1%, at most about 0.08%, at most about 0.05%, at most about 0.02%, at most about 0.01%, at most about 0.0075%, or at most about 0.005%) by weight of the polishing compositions described herein.

In one or more embodiments, the at least one (e.g., two or three distinct) nitride removal rate reducing agent includes a compound (e.g., a non-polymeric compound) that includes a hydrophobic portion containing a C₆ to C₄₀ hydrocarbon group (e.g., containing an alkyl group, an alkenyl group, an aryl group (e.g., phenyl), and/or an arylalkyl group (e.g., benzyl)); and a hydrophilic portion containing at least one group selected from the group consisting of a sulfinite group, a sulfate group, a sulfonate group, a carboxylate group, a phosphate group, and a phosphonate group. In one or more embodiments, the hydrophobic portion and the hydrophilic portion are separated by zero to ten (e.g., 1, 2, 3, 4, 5, 6, 7, 8, or 9) alkylene oxide groups (e.g., —(CH₂)ₙO— groups in which n can be 1, 2, 3, or 4). In one or more embodiments, the nitride removal rate reducing agent has zero alkylene oxide groups separating the hydrophobic portion and the hydrophilic portion. Without wishing to be bound by theory, it is believed that the presence of alkylene oxide groups within the nitride removal rate reducing agent may not be preferred in some embodiments as they may create slurry stability issues and increase silicon nitride removal rate.

In one or more embodiments, the nitride removal rate reducing agent has a hydrophobic portion containing a hydrocarbon group that includes at least 6 carbon atoms (C₆) (e.g., at least 8 carbon atoms (C₈), at least 10 carbon atoms (C₁₀), at least 12 carbon atoms (C₁₁), at least 14 carbon atoms (C₁₄), at least 16 carbon atoms (C₁₆), at least 18 carbon atoms (C₁₈), at least 20 carbon atoms (C₂₀), or at least 22 carbon atoms (C₂₂)) and/or at most 40 carbon atoms (C₄₀) (e.g., at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), or at most 22 carbon atoms (C₂₂)). The hydrocarbon groups mentioned herein refer to groups that contain carbon and hydrogen atoms and are optionally substituted by one or more halogens (e.g., F, Cl, Br, or I), C₁-C₄₀ alkoxy, or aryloxy. The hydrocarbon groups can include both saturated groups (e.g., linear, branched, or cyclic alkyl groups) and unsaturated groups (e.g., linear, branched, or cyclic alkyenyl groups; linear, branched, or cyclic alkynyl groups; or aromatic groups (e.g., phenyl, benzyl, or naphthyl)). In one or more embodiments, the hydrophilic portion of the nitride removal rate reducing agent contains at least one group selected from a phosphate group and a phosphonate group. It is to be noted that the term “phosphonate group” is expressly intended to include phosphonic acid groups.

In one or more embodiments, the nitride removal rate reducing agent is selected from the group consisting of lauryl phosphate, myristyl phosphate, cetyl phosphate, stearyl phosphate, octadecylphosphonic acid, oleyl phosphate, behenyl phosphate, octadecyl sulfate, lacceryl phosphate, oleth-3-phosphate, oleth-10-phosphate 1,4-phenylenediphosphonic acid, dodecylphosphonic acid, decylphosphonic acid, hexylphosphonic acid, octylphosphonic acid, phenylphosphonic acid, 1,8-octyldiphosphonic acid, 2,3,4,5,6-pentafluorobenzylphosphonic acid, heptadecafluorodecylphosphonic acid, and 12-pentafluorophenoxydodecylphosphonic acid.

In one or more embodiments, the nitride removal rate reducing agent can include an anionic polymer. In one or more embodiments, the anionic polymer can include one or more anionic groups, such as a sulfinite group, a sulfate group, a sulfonate group, a carboxylate group, a phosphate group, and a phosphonate group. In one or more embodiments, the anionic polymer is formed from one or more monomers selected from the group consisting of (meth)acrylic acid, maleic acid, acrylic acid, vinyl phosphonic acid, vinyl phosphoric acid, vinyl sulfonic acid, allyl sulfonic acid, styrene sulfonic acid, acrylamide, acrylamidopropyl sulfonic acid, and sodium phosphinite. In more specific embodiments, the anionic polymer can be selected from the group consisting of poly(4-styrenylsulfonic) acid (PSSA), polyacrylic acid (PAA), poly(vinylphosphonic acid) (PUPA), poly(2-acrylamido-2-methyl-1-propanesulfonic acid), poly(N-vinyl acetamide) (PNVA), polyethylenimine (PEI), anionic poly(methyl methacrylate) (PMMA), anionic polyacrylamide (PAM), polyaspartic acid (PASA), anionic poly(ethylene succinate) (PES), anionic polybutylene succinate (PBS), poly(vinyl alcohol) (PVA), 2-propenoic acid copolymer with 2-methyl-2-(1-oxo-2-propenyl)amino)-1-propanesulfonic acid monosodium salt and sodium phosphinite, 2-propenoic acid copolymer with 2-methyl-2-((1-oxo-2-propenyl)amino)-1-propanesulfonic acid monosodium salt and sodium hydrogen sulfite sodium salt, and 2-acrylamido-2-methyl-1-propanesulfonic acid-acrylic acid copolymer, poly(4-styrenesulfonic acid-co-acrylic acid-co-vinylphosphonic acid) terpolymer, and mixtures thereof. Without wishing to be bound by theory, it is believed that the anionic polymer can solubilize hydrophobic polishing materials and/defects on a wafer surface and facilitate their removal during a CMP process and/or post-CMP cleaning process.

In one or more embodiments, the anionic polymer can have a weight average molecular weight ranging from at least about 250 g/mol (e.g., at least about 500 g/mol, at least about 1000 g/mol, at least about 2,000 g/mol, at least about 5,000 g/mol, at least about 50,000 g/mol, at least about 100,000 g/mol, at least about 200,000 g/mol, or at least about 250,000 g/mol) to at most about 500,000 g/mol (e.g., at most about 400,000 g/mol, at most about 300,000 g/mol, at most about 200,000 g/mol, at most about 100,000 g/mol, or at most about 50,000 g/mol, or at most about 10,000 g/mol). In some embodiments, the at least one anionic polymer can have a weight average molecular weight ranging from at least about 1000 g/mol to at most about 10,000 g/mol. In some embodiments, the anionic polymer can have a weight average molecular weight ranging from at least about 2,000 g/mol to at most about 6,000 g/mol. In yet some embodiments, the anionic polymer can have a weight average molecular weight of about 5,000 g/mol.

In one or more embodiments, the at least one nitride removal rate reducing agent described herein can include both (1) at least one (e.g., two or three) compound (e.g., a non-polymeric compound) including a hydrophobic portion and a hydrophilic portion and (2) at least one (e.g., two or three) anionic polymer.

In one or more embodiments, the nitride removal rate reducing agent is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%) by weight to at most about 10% (e.g., at most about 9%, at most about 8%, at most about 7%, at most about 6%, at most about 5%, at most about 4%, at most about 3%, at most about 2%, at most about 1%, at most about 0.8%, at most about 0.6%, at most about 0.5%, at most about 0.4%, at most about 0.2%, at most about 0.1%, at most about 0.08%, at most about 0.05%, at most about 0.02%, at most about 0.0075%, or at most about 0.005%) by weight of the polishing compositions described herein. Without wishing to be bound by theory, it is believed that the nitride removal rate reducing agent described above can significantly decrease the polishing composition's removal rate for nitride substrate materials (e.g., silicon nitride), thus providing the ability to stop-on such substrate materials.

In one or more embodiments, the polishing compositions described herein can optionally include at least one (e.g., two or three) pH adjustor, if necessary, to adjust the pH to a desired value. In some embodiments, the at least one pH adjustor can be an acid (e.g., an organic or inorganic acid) or a base (e.g., an organic or inorganic base). For example, the pH adjustor can be selected from the group consisting of nitric acid, hydrochloric acid, sulfuric acid, propionic acid, citric acid, malonic acid, hydrobromic acid, hydroiodic acid, perchloric acid, ammonia, ammonium hydroxide, sodium hydroxide, potassium hydroxide, cesium hydroxide, monoethanolamine, diethanolamine, triethanolamine, methyl ethanolamine, methyldiethanolamine tetrabutylammonium hydroxide, tetrapropylammonium hydroxide, tetraethylammonium hydroxide, tetramethylammonium hydroxide, ethyltrimethylammonium hydroxide, diethyldimethylammonium hydroxide, dimethyldipropylammonium hydroxide, benzyltrimethylammonium hydroxide, tris(2-hydroxyethyl)methylammonium hydroxide, choline hydroxide, and any combinations thereof.

In one or more embodiments, the at least one pH adjuster is in an amount of from at least about 0.001% (e.g., at least about 0.005%, at least about 0.01%, at least about 0.05%, at least about 0.1%, at least about 0.2%, at least about 0.4%, at least about 0.5%, at least about 1% or at least about 1.5%) by weight to at most about 2.5% (e.g., at most about 2%, at most about 1.5%, at most about 1%, at most about 0.5%, at most about 0.1%, or at most about 0.5%) by weight of the polishing compositions described herein.

In one or more embodiments, the polishing compositions described herein can be either acidic or basic. In some embodiments, the polishing compositions can have a pH ranging from at least about 2 to at most about 9. For example, the pH can range from at least about 2 (e.g., at least about 2.5, at least about 3, at least about 3.5, at least about 4, at least about 4.5, or at least about 5) to at most about 9 (e.g., at most about 8.5, at most about 8, at most about 7.5, at most about 7, at most about 6.5, at most about 6, at most about 6.5, or at most about 5). In one or more embodiments, the polishing compositions described herein can have an acidic pH such as from about 2 to about 6 (e.g., from about 2 to about 4). Without wishing to be bound by theory, it is believed that, under such acidic conditions, the polishing compositions described herein can have an increased molybdenum removal rate and a reduced removal rate for nitride materials (e.g., silicon nitride).

In one or more embodiments, the polishing compositions described herein can include a solvent (e.g., a primary solvent), such as an aqueous solvent (e.g., water or a solvent including water and an organic solvent). In some embodiments, the solvent (e.g., water) is in an amount of from at least about 20% (e.g., at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, at least about 90%, at least about 92%, at least about 94%, at least about 95%, or at least about 97%) by weight to at most about 99% (e.g., at most about 98%, at most about 96%, at most about 94%, at most about 92%, at most about 90%, at most about 85%, at most about 80%, at most about 75%, at most about 70%, or at most about 65%) by weight of the polishing compositions described herein.

In one or more embodiments, an optional secondary solvent (e.g., an organic solvent) can be used in the polish compositions (e.g., a POU or concentrated polishing composition) of the present disclosure, which can help with the dissolution of an ingredient (e.g., an azole-containing corrosion inhibitor if present). In one or more embodiments, the secondary solvent can be one or more alcohols, alkylene glycols, or alkylene glycol ethers. In one or more embodiments, the secondary solvent includes one or more solvents selected from the group consisting of ethanol, 1-propanol, 2-propanol, n-butanol, propylene glycol, 2-methoxyethanol, 2-ethoxyethanol, propylene glycol propyl ether, and ethylene glycol.

In some embodiments, the secondary solvent is in an amount of from at least about 0.001% (e.g., at least about 0.005%, at least about 0.01%, at least about 0.02%, at least about 0.05%, at least about 0.1%, at least about 0.2%, at least about 0.4%, at least about 0.5%, at least about 0.6%, at least about 0.8%, at least about 1%, at least about 3%, at least about 5%, or at least about 10%) by weight to at most about 10% (e.g., at most about 7.5%, at most about 5%, at most about 3%, at most about 2%, at most about 1%, at most about 0.8%, at most about 0.6%, at most about 0.5%, or at most about 0.1%) by weight of the polishing compositions described herein.

In one or more embodiments, the polishing compositions described herein can further include at least one optional additive selected from the group consisting of chelating agents, azole compounds, oxidizers, surfactants, corrosion inhibitors, and water-soluble polymers.

The chelating agent is not particularly limited, but specific examples thereof include those in the group consisting of 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, ethylenediaminetetraacetic acid, diethylenetriaminepentaacetic acid, nitrilotriacetic acid, acetylacetone, aminotri(methylenephosphonic acid), 1-hydroxyethylidene (1,1-diphosphonic acid), 2-phosphono-1,2,4-butanetricarboxylic acid, hexamethylenediaminetetra(methylenephosphonic acid), ethylenediamine-tetra(methylenephosphonic acid), diethylenetriaminepenta(methylenephosphonic acid), salts thereof, and mixtures thereof.

In some embodiments, the chelating agent can be from at least about 0.001% (e.g., at least about 0.002%, at least about 0.003%, at least about 0.004%, at least about 0.005%, at least about 0.006%, at least about 0.007%, at least about 0.008%, at least about 0.009%, or at least about 0.01%) by weight to at most about 10% (e.g., at most about 9%, at most about 8%, at most about 7%, at most about 6%, at most about 5%, at most about 4%, at most about 3%, at most about 2%, at most about 1%, at most about 0.8%, at most about 0.6%, at most about 0.5%, at most about 0.4%, at most about 0.2%, at most about 0.1%, at most about 0.08%, at most about 0.05%, at most about 0.02%, at most about 0.0075%, or at most about 0.005%) by weight of the polishing compositions described herein.

The azole compound is not particularly limited, but specific examples thereof include heterocyclic azoles, substituted or unsubstituted triazoles (e.g., benzotriazoles), substituted or unsubstituted tetrazoles, substituted or unsubstituted diazoles (e.g., imidazoles, benzimidazoles, thiadiazoles, and pyrazoles), and substituted or unsubstituted benzothiazoles. Herein, a substituted diazole, triazole, or tetrazole refers to a product obtained by substitution of one or two or more hydrogen atoms in the diazole, triazole, or tetrazole with, for example, a carboxyl group, an alkyl group (e.g., a methyl, ethyl, propyl, butyl, pentyl, or hexyl group), a halogen group (e.g., F, Cl, Br, or I), an amino group, or a hydroxyl group. In one or more embodiments, the azole compound can be selected from the group consisting of tetrazole, benzotriazole, tolyltriazole, methyl benzotriazole (e.g., 1-methyl benzotriazole, 4-methyl benzotriazole, and 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole and 5-butyl benzotriazole), pentyl benzotriazole (e.g., 1-pentyl benzotriazole), hexyl benzotriazole (e.g., 1-hexyl benzotriazole and 5-hexyl benzotriazole), dimethyl benzotriazole (e.g., 5,6-dimethyl benzotriazole), chloro benzotriazole (e.g., 5-chloro benzotriazole), dichloro benzotriazole (e.g., 5,6-dichloro benzotriazole), chloromethyl benzotriazole (e.g., 1-(chloromethyl)-1-H-benzotriazole), chloroethyl benzotriazole, phenyl benzotriazole, benzyl benzotriazole, aminotriazole, aminobenzimidazole, pyrazole, imidazole, aminotetrazole, adenine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, aminotetrazole, tetrazole, phenyltetrazole, phenyl-tetrazole-5-thiol, and combinations thereof. Without wishing to be bound by theory, it is believed that the azole compounds can be used as a corrosion inhibitor in the polishing compositions described herein to reduce the removal of certain materials (e.g., metals or dielectric materials) during the polishing process.

In some embodiments, the azole compound can be from at least about 0.001% (e.g., at least about 0.002%, at least about 0.004%, at least about 0.005%, at least about 0.006%, at least about 0.008%, at least about 0.01%, at least about 0.02%, at least about 0.04%, at least about 0.05%, at least about 0.06%, at least about 0.08%, or at least about 0.1%) by weight to at most about 5% (e.g., at most about 4.5%, at most about 4%, at most about 3.5%, at most about 3%, at most about 2.5%, at most about 2%, at most about 1.5%, at most about 1%, at most about 0.9%, at most about 0.8%, at most about 0.7%, at most about 0.6%, at most about 0.5%, at most about 0.4%, at most about 0.3%, at most about 0.2%, at most about 0.18%, at most about 0.16%, at most about 0.15%, at most about 0.14%, at most about 0.12%, at most about 0.1%, at most about 0.08%, at most about 0.06%, at most about 0.05%, at most about 0.04%, at most about 0.03%, at most about 0.02%, or at most about 0.01%) by weight of the polishing compositions described herein.

The oxidizing agent is not particularly limited, but specific examples thereof include ammonium persulfate, potassium persulfate, hydrogen peroxide, ferric nitrate, diammonium cerium nitrate, iron sulfate, hypochlorous acid, ozone, potassium periodate, and peracetic acid. Without wishing to be bound by theory, it is believed that the oxidizing agent can facilitate the removal of materials during the polishing process.

In some embodiments, the oxidizing agent can be from at least about 0.01% (e.g., at least about 0.05, at least about 0.1%, at least about 0.2%, at least about 0.3%, at least about 0.4%, at least about 0.5%, at least about 0.6%, at least about 0.7%, at least about 0.8%, at least about 0.9%, at least about 1%, at least about 1.5%, or at least about 2%) by weight to at most about 10% (e.g., at most about 9%, at most about 8%, at most about 7%, at most about 6%, at most about 5%, at most about 4%, at most about 3%, at most about 2%, or at most about 1%) by weight of the polishing compositions described herein.

In one or more embodiments, the polishing compositions described herein can also include one or more surfactants selected from the group consisting of anionic surfactants, non-ionic surfactants, amphoteric surfactants, cationic surfactants, and mixtures thereof.

The cationic surfactant is not particularly limited, but specific examples thereof include aliphatic amine salts and aliphatic ammonium salts.

The non-ionic surfactant is not particularly limited, but specific examples thereof include an ether-type surfactant, an ether ester-type surfactant, an ester-type surfactant, and an acetylene-based surfactant. The ether-type surfactant is not particularly limited, but specific examples thereof include polyethylene glycol mono-4-nonylphenyl ether, polyethylene glycol monooleyl ether, and triethylene glycol monododecyl ether. The ether ester-type surfactant is not particularly limited, but a specific example thereof is a polyoxyethylene ether of a glycerin ester. The ester-type surfactant is not particularly limited, but specific examples thereof include a polyethylene glycol fatty acid ester, a glycerin ester, and a sorbitan ester. The acetylene-based surfactant is not particularly limited, but specific examples thereof include ethylene oxide adducts of acetylene alcohol, acetylene glycol, and acetylene diol.

The amphoteric surfactant is not particularly limited, but specific examples thereof include betaine-based surfactants.

The anionic surfactant is not particularly limited, but specific examples thereof include carboxylic acid salts, sulfonic acid salts, sulfate salts, and phosphate salts. The carboxylic acid salts are not particularly limited, but specific examples thereof include fatty acid salts (e.g., soaps) and alkyl ether carboxylic acid salts. Examples of the sulfonic acid salts include alkylbenzenesulfonic acid salts, alkylnaphthalenesulfonic acid salts, and α-olefin sulfonic acid salts. The sulfate salts are not particularly limited, but specific examples thereof include higher alcohol sulfate salts and alkyl sulfate salts. The phosphates are not particularly limited, but specific examples thereof include alkyl phosphates and alkyl ester phosphates.

The corrosion inhibitor is not particularly limited, but specific examples thereof include choline hydroxide, amino alcohols (e.g., monoethanolamine and 3-amino-4-octanol), amino acids (e.g., those described herein), and mixtures thereof.

The water-soluble polymer is not particularly limited, but specific examples thereof include polyacrylamide, polyvinyl alcohol, polyvinylpyrrolidone, polyacrylic acid, hydroxyethyl cellulose, and copolymers that include the polymers previously listed. Without wishing to be bound by theory, it is believed that the water-soluble polymer can serve as a removal rate inhibitor to reduce the removal rate of certain exposed materials on a substrate that do not intend to be removed or should be removed at a lower removal rate during the polishing process.

In one or more embodiments, the water-soluble polymer can be from at least about 0.01% (e.g., at least about 0.02%, at least about 0.03%, at least about 0.04%, at least about 0.05%, at least about 0.06%, at least about 0.07%, at least about 0.08%, at least about 0.09%, or at least about 0.1%) by weight to at most about 1% (e.g., at most about 0.8%, at most about 0.6%, at most about 0.5%, at most about 0.4%, at most about 0.2%, at most about 0.1%, at most about 0.08%, at most about 0.06%, or at most about 0.05%) by weight of the polishing compositions described herein.

In one or more embodiments, the polishing compositions described herein can be substantially free of one or more of certain ingredients, such as organic solvents, pH adjusting agents, fluorine-containing compounds (e.g., fluoride compounds or fluorinated compounds (such as fluorinated polymers/surfactants)), salts (e.g., halide salts or metal salts), polymers (e.g., non-ionic, cationic, or anionic polymers), quaternary ammonium compounds (e.g., salts such as tetraalkylammonium salts or hydroxides such as tetraalkylammonium hydroxide), corrosion inhibitors (e.g., azole or non-azole corrosion inhibitors), alkali bases (such as alkali hydroxides), silicon-containing compounds such as silanes (e.g., alkoxysilanes), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), polyols, inorganic acids (e.g., hydrochloric acid, sulfuric acid, phosphoric acid, or nitric acid), surfactants (e.g., cationic surfactants, anionic surfactants, non-polymeric surfactants, or non-ionic surfactants), plasticizers, oxidizing agents (e.g., H₂O₂ and periodic acid), corrosion inhibitors (e.g., azole or non-azole corrosion inhibitors), electrolytes (e.g., polyelectrolytes), and/or certain abrasives (e.g., ceria abrasives, non-ionic abrasives, surface modified abrasives, or negatively/positively charged abrasive). The halide salts that can be excluded from the polishing compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the polishing composition. In some embodiments, the polishing compositions described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the polishing compositions. In some embodiments, the polishing compositions described can be completely free of one or more of the above ingredients.

In one or more embodiments, the polishing compositions described herein can have a ratio (i.e., a removal rate ratio or selectivity) of a removal rate for molybdenum and/or its alloys to a removal rate for a nitride material (e.g., silicon nitride) of from at least about 2:1 (e.g., at least about 3:1, at least about 4:1, at least about 5:1, at least about 10:1, at least about 25:1, at least about 50:1, at least about 60:1, at least about 75:1, at least about 100:1, at least about 150:1, at least about 200:1, at least about 250:1, or at least about 300:1) to at most about 1000:1 (e.g., at most about 500:1, at most about 300:1, at most about 250:1, at most about 200:1, at most about 150:1, or at most about 100:1). In one or more embodiments, the polishing compositions described herein can have a ratio (i.e., a removal rate ratio or selectivity) of a removal rate for molybdenum and/or its alloys to a removal rate for an oxide material (e.g., silicon oxide such as TEOS) of from at least about 1:50 (e.g., at least about 1:45, at least about 1:40, at least about 1:35, at least about 1:30, at least about 1:25, at least about 1:20, at least about 1:15, at least about 1:10, at least about 1:8, at least about 1:6, at least about 1:5, at least about 1:4, at least about 1:2, or at least about 1:1) to at most about 50:1 (e.g., at most about 45:1, at most about 40:1, at most about 35:1, at most about 30:1, at most about 25:1, at most about 20:1, at most about 15:1, at most about 10:1, at most about 8:1, at most about 6:1, at most about 5:1, at most about 4:1, at most about 2:1, or at most about 1:1). In one or more embodiments, the ratios described above can be applicable when measuring removal rates for polishing either blanket wafers or patterned wafers (e.g., wafers including conductive layers, barrier layers, and/or dielectric layers).

In one or more embodiments, the molybdenum and/or TEOS removal rate can range from at least about 20 Å/min (e.g., at least about 30 Å/min, at least about 40 Å/min, at least about 50 Å/min, at least about 60 Å/min, at least about 70 Å/min, at least about 80 Å/min, at least about 90 Å/min, or at least about 100 Å/min) to at most about 600 Å/min (e.g., at most about 550 Å/min, at most about 500 Å/min, at most about 450 Å/min, at most about 400 Å/min, at most about 350 Å/min, at most about 300 Å/min, at most about 250 Å/min, at most about 200 Å/min, at most about 150 Å/min, or at most about 100 Å/min). In one or more embodiments, the nitride (e.g., silicon nitride) removal rate can be at most about 85 Å/min (e.g., at most about 80 Å/min, at most about 75 Å/min, at most about 70 Å/min, at most about 65 Å/min, at most about 60 Å/min, at most about 55 Å/min, at most about 50 Å/min, at most about 45 Å/min, at most about 40 Å/min, at most about 35 Å/min, at most about 30 Å/min, or at most about 25 Å/min, or at most about 20 Å/min, or at most about 15 Å/min, or at most about 10 Å/min, or at most about 5 Å/min, or essentially 0 Å/min).

In one or more embodiments, this disclosure features a method of polishing that can include applying a polishing composition according to the present disclosure to a substrate (e.g., a wafer such as a blanket wafer or a patterned wafer); and bringing a pad (e.g., a polishing pad) into contact with the surface of the substrate and moving the pad in relation to the substrate. In one or more embodiments, the substrate can include at least one of silicon oxides (e.g., tetraethyl orthosilicate (TEOS), high density plasma oxide (HDP), high aspect ratio process oxide (HARP), or borophosphosilicate glass (BPSG)), spin on films (e.g., films based on inorganic particle or films based on cross-linkable carbon polymer), silicon nitride, silicon carbide, high-K dielectrics (e.g., metal oxides of hafnium, aluminum, or zirconium), silicon (e.g., polysilicon, single crystalline silicon, or amorphous silicon), carbon, metals (e.g., tungsten, copper, cobalt, ruthenium, molybdenum, titanium, tantalum, or aluminum) or alloys thereof, metal nitrides (e.g., titanium nitride or tantalum nitride), and mixtures or combinations thereof. In one or more embodiments, the polishing method can include applying a polishing composition described herein to a substrate (e.g., a wafer) containing molybdenum and/or its alloys on a surface of the substrate.

In one or more embodiments, the method that uses a polishing composition described herein can further include producing a semiconductor device from the substrate treated by the polishing composition through one or more steps. For example, photolithography, ion implantation, dry/wet etching, plasma etching, deposition (e.g., PVD, CVD, ALD, ECD), wafer mounting, die cutting, packaging, and testing can be used to produce a semiconductor device from the substrate treated by the polishing composition described herein.

The specific examples below are to be construed as merely illustrative, and not limitative of the remainder of the disclosure in any way whatsoever. Without further elaboration, it is believed that one skilled in the art can, based on the description herein, utilize the present invention to its fullest extent.

### EXAMPLES

In these examples, the polishing was performed on 300 mm wafers using an AMAT Reflexion LK CMP polisher with a VP6000 pad or an H804 pad and a slurry flow rate of 175 mL/min or 300 mL/min.

The general compositions used in the examples are shown in Table 1 below. The specific details on the differences in the compositions tested will be explained in further detail when discussing the respective examples.

TABLE 1

| | % By Weight of the |
|---|---|
| Component | Composition |
| pH adjuster (base) | 0.005-1 |
| First Organic Acid | 0.1-3 |
| First amine (amino acid or alkylamine including a | 0.001-1 |
| 6-24 carbon alkyl group) | (if used) |
| Silicon Nitride Removal Rate Reducing Agent | 0.001-0.5 |
| | (if used) |
| Abrasive (silica) | 0.1-5 |
| Oxidizer | 0.1-5 |
| Solvent (DI Water) | 75-99 |
| pH | 2-6 |

### Example 1

The removal rates for TEOS, SiN, and molybdenum (Mo), along with the Mo static etch rate (SER) were measured for polishing compositions 1-5. The SER for Mo was measured by suspending Mo coupons in the polishing compositions at 45° C. for one minute. The removal rates were measured by polishing blanket wafers of the material indicated. Compositions 1-4 were identical except that (1) Composition 1 was a control and did not include an amine compound, (2) compositions 2-5 included an amino acid (as an amine compound described herein) in 1×, 2×, 3×, 4× concentrations, respectively. Compositions 1-5 all included 4× of a nitride removal rate reducing agent described herein. The test results are summarized in Table 2 below.

TABLE 2

| | Comp. 1 | Comp. 2 | Comp. 3 | Comp. 4 | Comp. 5 |
|---|---|---|---|---|---|
| SiN RR | N/A | 14 | 28 | 46 | 118 |
| (Å/min) | | | | | |
| TEOS RR | N/A | 146 | 142 | 110 | 120 |
| (Å/min) | | | | | |
| Mo RR | Cleared* | 448 | 368 | 262 | 306 |
| (Å/min) | | | | | |
| Mo SER | Cleared* | 28 | 21 | 18 | 17 |
| (Å/min) | | | | | |

*Cleared means that the RR/SER were so high that they were unable to be measured because the wafer was cleared of Mo

The results show that the amino acid (i.e., the amine compound described herein) in compositions 2-5 effectively reduced the molybdenum static etch rate, with increasing amounts showing more reduction. Composition 1, without an amine compound, was completely cleared of molybdenum material indicating that the composition was too aggressive of an environment for molybdenum. These results suggest that the amino acid compound can be used as a corrosion inhibitor for Mo during a CMP process.

### Example 2

The removal rates for TEOS, SiN, and Mo, along with the Mo static etch rate (SER) were measured as described above for polishing compositions 6-9. Compositions 6-9 were identical except for their differing pH values (i.e., 2.5, 3, 4, and 5, respectively). Compositions 6-9 included 1× of amino acid as an amine compound described herein and 4× of a nitride removal rate reducing agent described herein. The test results are summarized in Table 3 below.

TABLE 3

| | Comp. 6 | Comp. 7 | Comp. 8 | Comp. 9 |
|---|---|---|---|---|
| | (pH 2.5) | (pH 3) | (pH 4) | (pH 5) |
| SiN RR | 14 | 32 | 218 | 314 |
| (Å/min) | | | | |
| TEOS RR | 162 | 178 | 178 | 150 |
| (Å/min) | | | | |
| Mo RR | 524 | 440 | 204 | 175 |
| (Å/min) | | | | |
| Mo SER | 31 | 30 | 26 | 28 |
| (Å/min) | | | | |

The results show that a lower pH resulted in a higher Mo RR, although the SER was relatively stable from pH 2.5 to pH 5. The RR for SiN increased significantly at pH 4 and above.

### Example 3

The removal rates for TEOS, SiN, and Mo were measured for polishing compositions 10-13. Compositions 10-13 were identical except that composition 10 did not include any nitride removal rate reducing agent, while compositions 11-13 respectively included 1×, 2×, and 4× of a nitride removal rate reducing agent described herein. Compositions 10-13 all included 1× of an amino acid as an amine compound described herein. The test results are summarized in Table 4 below.

TABLE 4

| | Comp. 10 | Comp. 11 | Comp. 12 | Comp. 13 |
|---|---|---|---|---|
| SiN RR (Å/min) | 158 | 48 | 32 | 16 |
| TEOS RR (Å/min) | 190 | 194 | 178 | 168 |
| Mo RR (Å/min) | 366 | 436 | 440 | 440 |

The results show that the nitride removal rate reducing agent described herein significantly reduced SiN RR. Further, the nitride removal rate reducing agent did not have an appreciable influence on the TEOS or Mo removal rates.

### Example 4

The removal rates for TEOS, SiN, and Mo, along with the Mo static etch rate (SER) were measured as described above for polishing compositions 14-17. Compositions 14-17 were identical except that they included 0×, 1×, 2×, and 3×, respectively, of an alkylamine including a 6-24 carbon alkyl group as an amine compound described herein. Compositions 14-17 all included 2× of a nitride removal rate reducing agent described herein. The results are summarized in Table 5 below.

TABLE 5

| | Comp. 14 | Comp. 15 | Comp. 16 | Comp. 17 |
|---|---|---|---|---|
| SiN RR (Å/min) | N/A | 40 | 44 | 41 |
| TEOS RR (Å/min) | N/A | 216 | 204 | 266 |
| Mo RR (Å/min) | Cleared* | 140 | 90 | 98 |
| Mo SER (Å/min) | Cleared* | 3.8 | 3.4 | 0.2 |

*Cleared means that the RR/SER were so high that they were unable to be measured because the wafer was cleared of Mo

The results show that the addition of an alkylamine including a 6-24 carbon alkyl group as an amine compound significantly reduced the Mo RR and SER, while not appreciably influencing the removal rates of TEOS or SiN.

### Example 5

The Mo SER was measured as described above for polishing compositions 18-22. Compositions 18 was a control that did not include any amine compound. Compositions 19-22 included the same components as composition 18 except that compositions 19-22 included the same wt % of a 6 carbon, 8 carbon, 12 carbon, and 16 carbon alkylamine compound, respectively. All of the compositions included the same amount of all other components, with composition 18 including slightly more water due to the lack of alkylamine. The results are summarized in Table 6 below.

TABLE 6

| | Comp. 18 | Comp. 19 | Comp. 20 | Comp. 21 | Comp. 22 |
|---|---|---|---|---|---|
| Mo SER | 21.67 | 10.72 | 4.42 | 0.86 | 0.6 |
| (Å/min) | | | | | |

The results show that the addition of an alkylamine compound resulted in a significant reduction in the Mo SER when compared with the control (Comp. 18). Further, the reduction in Mo SER is increased as the carbon chain length is increased from 6 carbons to 16 carbons. The SER measurements for Comp. 21 and Comp. 22 indicate that very minimal Mo corrosion occurred and a very protective environment for Mo was provided, which should provide for controlled polishing rate with few defects.

### Example 6

The removal rates for TEOS, SiN, and Mo were measured for polishing compositions 23-25. Compositions 23-25 were identical except that they included a C6, a C12, and a C18 nitride removal rate reducing agent, respectively. Compositions 23-25 all included the same amino acid as an amine compound described herein. The test results are summarized in Table 7 below.

TABLE 7

| | Comp. 23 | Comp. 24 | Comp. 25 |
|---|---|---|---|
| SiN RR | 84.5 | 15.6 | 5.35 |
| (Å/min) | | | |
| TEOS RR | 600 | 531 | 381 |
| (Å/min) | | | |
| Mo RR | 553 | 518 | 410 |
| (Å/min) | | | |

The results show that the silicon nitride removal rate progressively decreased as the carbon chain length was increased in the nitride removal rate reducing agent. The TEOS and Mo removal rates show a similar progress but in a smaller magnitude. Thus, the above results suggest that the longer carbon chain in a nitride removal rate reducing agent may be able to provide a more effective stop-on nitride.

### Example 7

The Mo SER and removal rates for TEOS, SiN, and Mo were measured for polishing compositions 26-29. Compositions 26-29 were identical except that they each included a different amino acid as an amine compound described herein. Compositions 26-29 all included the same nitride removal rate reducing agent. The test results are summarized in Table 8 below.

TABLE 8

| | Comp. 26 | Comp. 27 | Comp. 28 | Comp. 29 |
|---|---|---|---|---|
| | (Histidine) | (Arginine) | (Glycine) | (Lysine) |
| SiN RR (Å/min) | 30 | 30 | 116 | 40 |
| TEOS RR (Å/min) | 178 | 204 | 218 | 186 |
| Mo RR (Å/min) | 440 | 362 | 728 | 312 |
| Mo SER (Å/min) | 30 | 30 | 116 | 40 |

The results show that Composition 28 was unable to adequately protect Mo (i.e., high SER and RR) when compared with the other compositions. Further, composition 28 also showed a significantly increased SiN RR. The above results suggest that an amino acid containing at least two amino groups (e.g., histidine, arginine, and lysine) exhibited superior corrosion inhibition toward Mo compared to an amino acid containing only one amino group (e.g., glycine).

While this disclosure has been described with respect to the examples set forth herein, it is understood that other modifications and variations are possible without departing from the spirit and scope of the disclosure as defined in the appended claims.

1. A polishing composition, comprising:
at least one abrasive;
at least one organic acid or a salt thereof;
at least one amine compound, the at least one amine compound comprising an amino acid, an alkylamine having a 6-24 carbon alkyl chain, or a mixture thereof;
at least one nitride removal rate reducing agent; and
an aqueous solvent;
wherein the polishing composition has a pH of about 2 to about 9.

2. The polishing composition of claim 1, wherein the at least one abrasive is selected from the group consisting of alumina, silica, titania, ceria, zirconia, co-formed products of alumina, silica, titania, ceria, or zirconia, coated abrasives, surface modified abrasives, and mixtures thereof.

3. The polishing composition of claim 1, wherein the at least one abrasive is in an amount of from about 0.01% to about 50% by weight of the composition.

4. The polishing composition of claim 1, wherein the at least one organic acid is selected from the group consisting of gluconic acid, lactic acid, citric acid, tartaric acid, malic acid, glycolic acid, malonic acid, formic acid, oxalic acid, acetic acid, propionic acid, peracetic acid, succinic acid, lactic acid, amino acetic acid, phenoxyacetic acid, bicine, diglycolic acid, glyceric acid, and mixtures thereof.

5. The polishing composition of claim 1, wherein the at least one organic acid is in an amount of from about 0.001% to about 10% by weight of the composition.

6. The polishing composition of claim 1, wherein the at least one amine compound is selected from the group consisting of tricine, alanine, histidine, valine, phenylalanine, proline, glutamine, aspartic acid, glutamic acid, arginine, lysine, tyrosine, serine, leucine, isoleucine, glycine, tryptophan, asparagine, cysteine, methionine, aspartate, glutamate, threonine, taurine, hexylamine, octylamine, decylamine, dodecylamine, tetradecylamine, hexadecylamine, octadecylamine, and mixtures thereof.

7. The polishing composition of claim 1, wherein the at least one amine compound is in an amount of from about 0.001% to about 5% by weight of the composition.

8. The polishing composition of claim 1, wherein the at least one nitride removal rate reducing agent comprises:
a hydrophobic portion comprising a C₆ to C₄₀ hydrocarbon group; and
a hydrophilic portion comprising at least one group selected from the group consisting of a sulfinite group, a sulfate group, a sulfonate group, a carboxylate group, a phosphate group, and a phosphonate group; and
wherein the hydrophobic portion and the hydrophilic portion are separated by zero to ten alkylene oxide groups.

9. The polishing composition of claim 8, wherein the hydrophobic portion comprises a C₁₂ to C₃₂ hydrocarbon group.

10. The polishing composition of claim 8, wherein the hydrophilic portion comprises a phosphate group or a phosphonate group.

11. The polishing composition of claim 8, wherein the at least one nitride removal rate reducing agent has zero alkylene oxide group separating the hydrophobic portion and the hydrophilic portion.

12. The polishing composition of claim 1, wherein the at least one nitride removal rate reducing agent is selected from the group consisting of lauryl phosphate, myristyl phosphate, cetyl phosphate, stearyl phosphate, octadecylphosphonic acid, oleyl phosphate, behenyl phosphate, octadecyl sulfate, lacceryl phosphate, oleth-3-phosphate, oleth-10-phosphate, 1,4-phenylenediphosphonic acid, dodecylphosphonic acid, decylphosphonic acid, hexylphosphonic acid, octylphosphonic acid, phenylphosphonic acid, 1,8-octyldiphosphonic acid, 2,3,4,5,6-pentafluorobenzylphosphonic acid, heptadecafluorodecylphosphonic acid, and 12-pentafluorophenoxydodecylphosphonic acid.

13. The polishing composition of claim 1, wherein the at least one nitride removal rate reducing agent comprises an anionic polymer.

14. The polishing composition of claim 13, wherein the at least one nitride removal rate reducing agent comprises poly(4-styrenylsulfonic) acid (PSSA), polyacrylic acid (PAA), poly(vinylphosphonic acid) (PVPA), poly(2-acrylamido-2-methyl-1-propanesulfonic acid), poly(N-vinyl acetamide) (PNVA), anionic poly(methyl methacrylate) (PMMA), anionic polyacrylamide (PAM), polyaspartic acid (PASA), anionic poly(ethylene succinate) (PES), anionic polybutylene succinate (PBS), poly(vinyl alcohol) (PVA), 2-propenoic acid copolymer with 2-methyl-2-((1-oxo-2-propenyl)amino)-1-propanesulfonic acid monosodium salt and sodium phosphinite, 2-propenoic acid copolymer with 2-methyl-2-((1-oxo-2-propenyl)amino)-1-propanesulfonic acid monosodium salt and sodium hydrogen sulfite sodium salt, 2-acrylamido-2-methyl-1-propanesulfonic acid-acrylic acid copolymer, poly(4-styrenesulfonic acid-co-acrylic acid-co-vinylphosphonic acid) terpolymer, or a mixture thereof.

15. The polishing composition of claim 1, wherein the at least one nitride removal rate reducing agent is from 0.001% to about 10% by weight of the composition.

16. The polishing composition of claim 1, further comprising at least one azole compound.

17. The polishing composition of claim 16, wherein the at least one azole compound is from 0.001% to about 5% by weight of the composition.

18. The polishing composition of claim 1, further comprising:
an organic solvent in an amount of from about 0.001% to about 10% by weight of the composition.

19. The polishing composition of claim 18, wherein the organic solvent is selected from the group consisting of ethanol, 1-propanol, 2-propanol, n-butanol, propylene glycol, 2-methoxyethanol, 2-ethoxyethanol, propylene glycol propyl ether, ethylene glycol, and any combinations thereof.

20. A method, comprising:
applying the polishing composition of claim 1 to a substrate comprising molybdenum or an alloy thereof on a surface of the substrate; and
bringing a pad into contact with the surface of the substrate and moving the pad in relation to the substrate.

21. The method of claim 20, further comprising forming a semiconductor device from the substrate.
